(19) United States
(12) Patent Application Publication
(10) Pub. No.: US 2009/0004848 A1
(43) Pub. Date: Jan. 1, 2009

(54) METHOD FOR FABRICATING INTERCONNECTION IN SEMICONDUCTOR DEVICE

(76) Inventors: Choon Hwan Kim, Seongnam-si (JP); II Cheol Rho, Icheon-si (KR)

Correspondence Address: MARSHALL, GERSTEIN & BORUN LLP, 233 S. WACKER DRIVE, SUITE 6300, SEARS TOWER, CHICAGO, IL, 60606, US

(21) Appl. No.: 11/951,636

(22) Filed: Dec. 6, 2007

(30) Foreign Application Priority Data
Jun. 28, 2007 (KR) 10-2007-0064756

(51) Int. Cl. H01L 21/4763

(52) U.S. Cl. 438/644; 257/E21.495

(57) ABSTRACT

A method for fabricating an interconnection in a semiconductor device includes forming a hydrogenated tungsten nucleation layer on a semiconductor substrate, and forming a bulk tungsten layer on the tungsten nucleation layer. Boron ions react with a hydrogen gas supplied together with a diborane gas to be restored to a diborane again, thereby preventing a boron layer from being formed on an interface of the tungsten nucleation layer.

### CROSS-REFERENCE TO RELATED APPLICATIONS

Priority to Korean Patent application number 10-2007-0064756, filed on Jun. 28, 2007, the disclosure of which is hereby incorporated by reference herein in its entirety, is claimed.

### BACKGROUND OF THE INVENTION

The present invention relates to a method for fabricating a semiconductor device, and more particularly, to a method for fabricating an interconnection in a semiconductor device.

As the minimum line width of a semiconductor device decreases, resistances of a contact plug or an ohmic contact increases. In fabrication of a semiconductor device, a metal interconnection or bit line is frequently formed of tungsten which has a low resistivity. Tungsten has been used for the ohmic contact and bit line so as to compensate for the increase in resistance due to the reduction of the bit line width and to reduce a sheet resistance. Therefore, much research has been conducted to reduce the resistance of tungsten.

As one example, the resistivity of tungsten is reduced by forming a tungsten nucleation layer and a bulk tungsten layer. More specifically, the nucleation layer is formed using diborane (B₂H₆) gas or tungsten hexafluoride (WF₆) gas as a source gas. A tungsten layer having a large grain size is formed on the nucleation layer. In this way, the resistivity of tungsten can be reduced.

However, due to the diborane (B₂H₆) gas used in forming the nucleation layer, a boron layer is formed on the nucleation layer, so that adhesion to a tungsten layer is reduced. Specifically, there may exist diborane (B₂H₆) gas that does not react with the tungsten hexafluoride (WF₆) gas in the formation of the nucleation layer. Accordingly, the supersaturated diborane (B₂H₆) gas is decomposed into boron ions, which forms a boron layer on the tungsten nucleation layer.

The boron ions in the boron layer can penetrate a semiconductor substrate, thereby causing degradation in electrical properties of a semiconductor device. Further, a peeling phenomenon may occur, which causes the tungsten layer to come off a bulk tungsten layer due to the reduction of the adhesion to the bulk tungsten layer.

### SUMMARY OF THE INVENTION

In one embodiment, a method for fabricating an interconnection in a semiconductor device includes: forming a hydrogenated tungsten nucleation layer on a semiconductor substrate; and forming a bulk tungsten layer on the tungsten nucleation layer. The method further may include forming an adhesive layer on the semiconductor substrate prior to forming the tungsten nucleation layer. The adhesive layer may include a titanium layer and a titanium nitride layer. The forming of the hydrogenated tungsten nucleation layer may include in an alternating sequence injecting a tungsten hexafluoride gas and a hydrogenated diborane gas. The forming of the hydrogenated tungsten nucleation layer may include repeating a reaction cycle comprising sequentially supplying a tungsten hexafluoride gas, a purge gas, a hydrogen and diborane gas, and a purge gas to the semiconductor substrate. The tungsten nucleation layer may be formed in a stacked multilayer structure. The tungsten nucleation layer is formed at a predetermined temperature within a preferred range of approximately 250° C. to approximately 400° C.

In another embodiment, a method for fabricating an interconnection in a semiconductor device includes forming a tungsten nucleation layer on a semiconductor substrate by alternately injecting a tungsten hexafluoride gas and a hydrogenated diborane gas; and forming a bulk tungsten layer on the tungsten nucleation layer. The method further may include forming an adhesive layer on the semiconductor substrate prior to forming the tungsten nucleation layer. The adhesive layer may include a titanium layer and a titanium nitride layer. The forming of the tungsten nucleation layer may include repeating a reaction cycle comprising sequentially supplying a tungsten hexafluoride gas, a purge gas, a hydrogenated diborane gas, and a purge gas to the semiconductor substrate. The forming of the hydrogenated tungsten nucleation layer may include repeating a reaction cycle comprising sequentially supplying a tungsten hexafluoride gas, a purge gas, a hydrogen and diborane gas, and a purge gas to the semiconductor substrate. The tungsten nucleation layer is formed at a predetermined temperature within a preferred range of approximately 250° C. to approximately 400° C.

### BRIEF DESCRIPTION OF THE DRAWINGS

FIGS. 1 to 4 illustrate a method for fabricating an interconnection in a semiconductor device according to the present invention.

FIG. 5 illustrates a process of forming a tungsten nucleation layer according one embodiment of the present invention.

### DESCRIPTION OF SPECIFIC EMBODIMENTS

Hereinafter, a method for fabricating an interconnection in a semiconductor device according to the present invention will be described in detail with reference to the accompanying drawings.

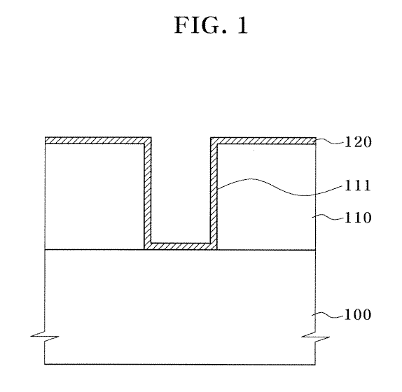

FIGS. 1 to 4 illustrate a method for fabricating an interconnection in a semiconductor device according to one embodiment of the present invention.

Referring to FIG. 1, an interlayer dielectric layer 110 is formed on a semiconductor substrate 100 having a lower structure (not shown). For example, in a memory device such as DRAM, prior to the formation of the interlayer dielectric layer 110, an isolation layer is formed by a shallow trench isolation (STI) process. The isolation layer defines an active region in the semiconductor substrate 100. Then, a transistor including a source/drain region and a gate electrode may be formed in the active region of the semiconductor substrate 100.

The interlayer dielectric layer 110 is selectively etched to form a bit line contact hole 111. Specifically, after a photolithography process using an etch mask (not shown) is performed to form the bit line contact hole 111 on the interlayer dielectric layer 110, the interlayer dielectric layer 110 exposed by the etch mask is selectively etched to form the bit line contact hole 111. At this point, the active region on the semiconductor substrate 100 or a contact pad connected thereto may be exposed by the bit line contact hole 111.

An adhesive layer 120 is formed over the semiconductor substrate 100 where the bit line contact hole 111 is formed. The adhesive layer 120 may include a titanium layer and a titanium nitride layer. The titanium layer may improve adhesion of a tungsten nucleation layer which will be formed later. The titanium nitride layer can prevent titanium of the titanium layer from reacting with a tungsten hexafluoride (WF₆) gas.

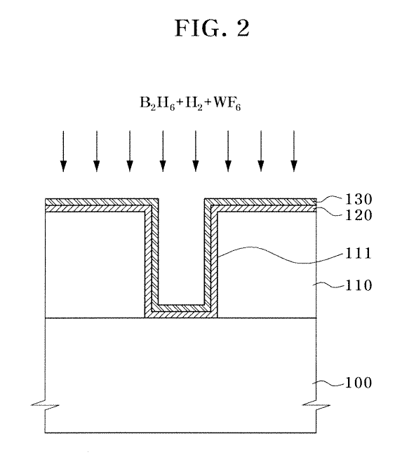

Referring to FIG. 2, a tungsten nucleation layer 130 is formed on the adhesive layer 120 over the semiconductor substrate 100. The tungsten nucleation layer 130 can be formed by alternately injecting a tungsten hexafluoride gas, a diborane gas and a hydrogen gas. Also, a pulsed nucleation layer (PNL) process or an atomic layer deposition (ALD) method may be performed to form the tungsten nucleation layer 130.

Before the tungsten nucleation layer 130 is formed, the semiconductor substrate 100 with the bit line contact hole 111 thereon is loaded into a reaction chamber. Then, preferably a tungsten hexafluoride (WF₆) gas, a purge gas, a hydrogenated diborane (B₂H₆) gas and a purge gas are sequentially injected into the reaction chamber. That is, a reaction cycle for forming the tungsten nucleation layer 130 is repeatedly performed to form a tungsten nucleation layer 130 with a stacked multilayer structure. The tungsten nucleation layer 130 is formed at a predetermined temperature preferably within a range of approximately 250° C. to approximately 400° C.

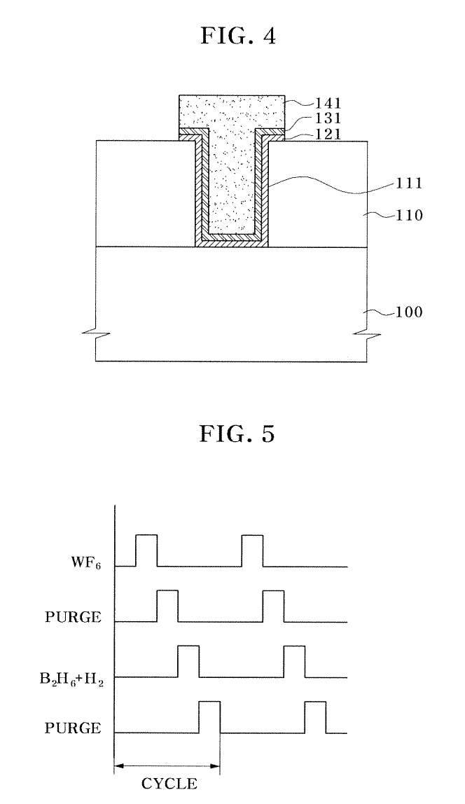

Referring to FIG. 5, a tungsten hexafluoride (WF₆) gas is supplied into the reaction chamber. The supplied tungsten hexafluoride (WF₆) gas may be chemically or physically adsorbed onto a semiconductor substrate.

Next, a purge gas is supplied into the reaction chamber. The purge gas may include an inert gas such as nitrogen (N₂), argon (Ar), and helium (He), which can exhaust or purge off unadsorbed tungsten hexafluoride (WF₆) gas.

Next, a hydrogenated diborane (B₂H₆) gas is supplied into the reaction chamber. In this case, the diborane (B₂H₆) gas and hydrogen (H₂) gas may be together supplied into the reaction chamber. The supplied diborane (B₂H₆) gas reacts with the tungsten hexafluoride (WF₆) gas adsorbed onto the semiconductor substrate to form a tungsten nucleation layer.

On the other hand, excess diborane (B₂H₆) gas may remain in the reaction chamber after reacting with the tungsten fluoride (WF₆) gas adsorbed onto the semiconductor substrate. The remaining diborane (B₂H₆) gas is decomposed into boron ions, and the boron ions can be restored to a diborane (B₂H₆) again by a reaction with a hydrogen (H₂) gas supplied together with the diborane (B₂H₆) gas.

Therefore, diborane (B₂H₆) gas and hydrogen (H₂) gas may be together supplied into the reaction chamber in a process of forming the tungsten nucleation layer, so that an adhesion rate of the boron ions decomposed from the excess diborane (B₂H₆) gas can be reduced, thereby preventing a boron layer from being formed on an interface of the tungsten nucleation layer.

A purge gas is next supplied into the reaction chamber. The purge gas may include an inert gas such as nitrogen (N₂), argon (Ar), and helium (He), which can exhaust or purge off a remaining gas such as the excess diborane (B₂H₆) gas or the diborane (B₂H₆) gas restored by the hydrogen (H₂) gas in the reaction chamber.

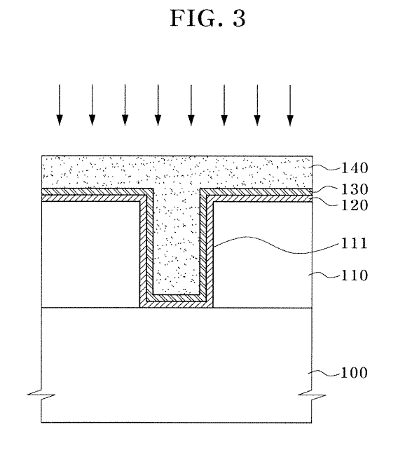

Referring to FIG. 3, a bulk tungsten layer 140 is formed on the tungsten nucleation layer 130. The bulk tungsten layer 140 may use tungsten hexafluoride (WF₆) as a tungsten source gas, and use hydrogen (H₂) gas as a reduction gas. The bulk tungsten layer 140 is grown on the tungsten nucleation layer 130 by a reaction between the tungsten source gas and the hydrogen (H₂) gas. At this point, a boron layer is repressed by reduction reaction with the hydrogen (H₂) gas so that adhesion between the tungsten nucleation layer 130 and the bulk tungsten layer 140 may be improved. Accordingly, resistivity of the tungsten layer and resistance of the bit line are reduced, so that an operation speed of a semiconductor device can be increased.

Referring to FIG. 4, a photolithography process may be performed to sequentially pattern the bulk tungsten layer, the tungsten nucleation layer and the adhesive layer for forming a bit line contact and a bit line which includes a bulk tungsten layer pattern 141, a tungsten nucleation layer pattern 131 and an adhesive layer pattern 121.

Embodiments of the present invention can be applied to other processes which deposit tungsten using the described method, e.g., a case of forming a gate electrode with tungsten or forming tungsten in a process of fabricating a metal interconnection.

Although preferred embodiments of the invention have been disclosed for illustrative purposes, those skilled in the art will appreciate that various modifications, additions and substitutions are possible, without departing from the scope and spirit of the invention as defined in the accompanying claims.

What is claimed is:

1. A method for fabricating an interconnection in a semiconductor device, comprising:
forming a hydrogenated tungsten nucleation layer on a semiconductor substrate; and
forming a bulk tungsten layer on the tungsten nucleation layer.

2. The method of claim 1, further comprising forming an adhesive layer on the semiconductor substrate prior to forming the tungsten nucleation layer.

3. The method of claim 2, comprising forming the adhesive layer of a titanium layer and a titanium nitride layer.

4. The method of claim 1, comprising forming the hydrogenated tungsten nucleation layer by a process comprising alternately injecting a tungsten hexafluoride gas and a hydrogenated diborane gas.

5. The method of claim 1, comprising forming the hydrogenated tungsten nucleation layer by a process comprising repeating a reaction cycle comprising sequentially supplying a tungsten hexafluoride gas, a purge gas, a hydrogen and diborane gas, and a purge gas to the semiconductor substrate.

6. The method of claim 1, comprising forming the tungsten nucleation layer in a stacked multilayer structure.

7. The method of claim 1, comprising forming the tungsten nucleation layer at a predetermined temperature within a range of approximately 250° C. to approximately 400° C.

8. A method for fabricating an interconnection in a semiconductor device, comprising:
forming a tungsten nucleation layer on a semiconductor substrate by alternately injecting a tungsten hexafluoride gas and a hydrogenated diborane gas; and
forming a bulk tungsten layer on the tungsten nucleation layer.

9. The method of claim 8, further comprising forming an adhesive layer on the semiconductor substrate prior to forming the tungsten nucleation layer.

10. The method of claim 9, comprising forming the adhesive layer of a titanium layer and a titanium nitride layer.

11. The method of claim 8, wherein the forming of the tungsten nucleation layer comprises repeating a reaction cycle comprising sequentially supplying a tungsten hexafluoride gas, a purge gas, a hydrogenated diborane gas, and a purge gas to the semiconductor substrate.

12. The method of claim 8, wherein the forming of the hydrogenated tungsten nucleation layer comprises repeating a reaction cycle comprising sequentially supplying a tungsten hexafluoride gas, a purge gas, a hydrogen and diborane gas, and a purge gas to the semiconductor substrate.

13. The method of claim 8, wherein the tungsten nucleation layer is formed at a predetermined temperature within a range of approximately 250° C. to approximately 400° C.
